(19) United States
(12) Patent Application Publication
(10) Pub. No.: US 2008/0239646 A1
(43) Pub. Date: Oct. 2, 2008

(54) BEZEL MOUNTING ASSEMBLY

(75) Inventors: YUN-LUNG CHEN, Taipei Hsien (TW); QING-HAO WU, Shenzhen (CN); CHUAN-LIN ZHENG, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD, Shenzhen City (CN); HON HAI PRECISION INDUSTRY CO., LTD., Taipei Hsien (TW)

(21) Appl. No.: 11/829,976

(22) Filed: Jul. 30, 2007

(30) Foreign Application Priority Data
Mar. 27, 2007 (CN) 200720200182.2

(51) Int. Cl. G06F 1/16; A47B 81/00; H05K 7/14

(52) U.S. Cl. 361/683; 312/223.2; 361/726

(57) ABSTRACT

A bezel mounting assembly includes a chassis (10), a bezel (30), and a latch member (50) for securing the bezel to the chassis. The chassis includes a front panel (11), and a pair of fixing holes (13) defined in the front panel. The bezel includes a pair of fixing pieces (34) inserted through the fixing holes (13) of the chassis. Each fixing piece has a hook (341) formed at a distal end thereof. The latch member includes a pair of securing pieces (54) engaged with the hooks of the bezel for securely fixing the bezel, and a pair of resilient arms (52) capable of being elastically deformed to urge the securing pieces of the latch member disengaging from the hooks of the bezel. The resilient arms are connected between the securing pieces.

### BACKGROUND

1. Field of the Invention

The present invention relates to mounting assemblies and more particularly to a computer bezel mounting assembly with simplified configuration.

2. Description of Related Art

A typical bezel mounting assembly is usually directly mounted to a computer case with a plurality of screws. However, a screwdriver or other tool is required for installation or removal of the screws, which is inconvenient and time consuming. U.S. Pat. No. 7,166,799 discloses an improved bezel mounting assembly including a front panel, a first operating member, a bezel, and a second operating member. The panel defines a plurality of slots. The first operating member is pivotally engaged with the panel and includes a handle. The handle is connected with a pushing portion. The bezel forms a plurality of hooks, one pair of hooks for primary connection respectively include a guiding block. The second operating member is rotatably mounted to the bezel and includes a driving portion with a convex cam portion. The bezel is engaged with the panel by the hooks, in disassembly, the handle is rotated, then the pushing portion presses the cam portion of the second operating member, and the pressing arms push the guiding block and make the hooks deform, thereby detaching the bezel from the panel. However, the mounting assembly utilizes a plurality of additional separated members with specific configurations to mount the front bezel, which is more time-consuming to manufacture and not cost saving.

What is needed, therefore, is a simplified computer bezel mounting assembly.

### SUMMARY

A bezel mounting assembly includes a chassis, a bezel, and a latch member for securing the bezel to the chassis. The chassis includes a front panel, and a pair of fixing holes defined in the front panel. The bezel includes a pair of fixing pieces inserted through the fixing holes of the chassis. Each fixing piece has a hook formed at a distal end thereof. The latch member includes a pair of securing pieces engaged with the hooks of the bezel for securely fixing the bezel, and a pair of resilient arms capable of being elastically deformed to urge the securing pieces of the latch member to disengage from the hooks of the bezel. The resilient arms are connected between the securing pieces.

Other advantages and novel features will be drawn from the following detailed description of preferred embodiments with attached drawings, in which:

### BRIEF DESCRIPTION OF THE DRAWINGS

FIG. 1 is an exploded view of a bezel mounting assembly in accordance with the present invention, the bezel mounting assembly including a bezel, a chassis, and a latch member;

FIG. 2 is an enlarged view of the latch member of FIG. 1, but viewed from another aspect;

FIG. 3 is a fully assembled view of FIG. 1, showing the lock member in a natural state to lock the bezel; and

FIG. 4 is similar to FIG. 3, but showing the lock member in an elastically deformed state to unlock the bezel.

### DETAILED DESCRIPTION OF THE EMBODIMENT

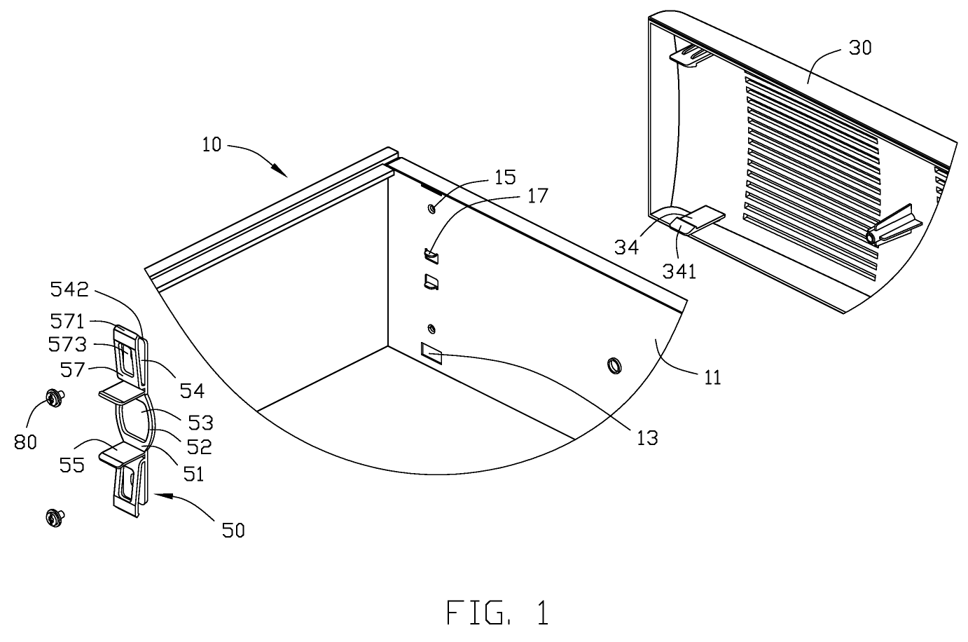

Referring to FIG. 1, a bezel mounting assembly in accordance with a preferred embodiment of the present invention, includes a chassis 10, a bezel 30, and a latch member 50 for securing the bezel 30 to the chassis 10.

The panel 30 includes a pair of resilient fixing pieces 34 respectively protruded from upper and lower portions of an interior surface thereof towards the chassis 10. Each fixing piece 34 has a hook 341 formed at a distal end thereof.

The chassis 10 includes a front panel 11. A pair of rectangular fixing holes 13 corresponding to the fixing pieces 34 of the panel 30 are defined in upper and lower portions of the front panel 11 respectively. A pair of screw holes 15 is defined in the front panel 11 between the fixing holes 13. A pair of stop pieces 17 protrudes perpendicularly and inwardly from the front panel 11 between the screw holes 15. The fixing holes 13, the screw holes 15, and the stop pieces 17 are located approximately in a line parallel to a side edge of the front panel 11.

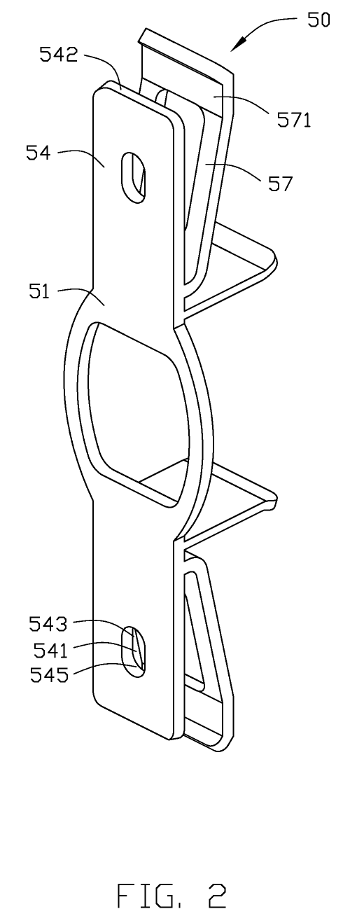

Referring to FIG. 1 and FIG. 2, the latch member 50 includes an elongated body 51. A pair of securing pieces 54 is respectively formed at upper and lower ends of the body 51, a pair of resilient arms 52 is connected between the securing pieces 54, and an opening 53 surrounded by the securing pieces 54 and the resilient arms 52 is defined in the body 51. The resilient arms 52 are arc-shaped and protrude out a short distance from two side edges of the body 51. Each securing piece 54 has a distal end 542. A distance between the ends 542 of the securing piece 54 is approximately equal to that between the fixing holes 13 of front panel 11 of the chassis 10. Each securing piece 54 has an elongated slot 541. Each slot 541 has an inner end 543 near a central portion of the body 51, and an outer end 545 further from the central portion of the body 51. A distance between the inner ends 543 of the two slots 541 is approximately equal to that between the screw holes 15 of the front panel 11 of the chassis 10. A pair of handles 55 is bent perpendicularly from junction ends of the two securing pieces 54 respectively. A pair of resisting pieces 57 extends obliquely from the junction ends respectively. Each resisting piece 57 includes a flange 571 bent from its distal end towards the distal end 542 of the securing piece 54, and an opening 573 facing the slot 541 of the securing piece 54 defined therein.

A guiding post 80 such as a screw, includes a wide head and a narrow shaft connecting with the head. A diameter of the head is greater than a width of the slot 541 of the latch member 50, and a diameter of the shaft is not more than the width of the slot 541.

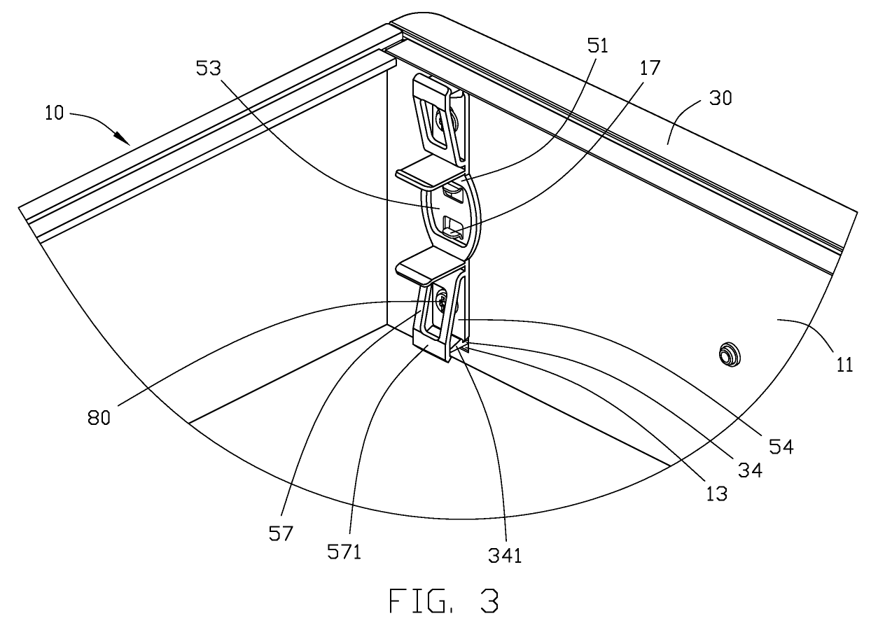

Referring to FIG. 1 to FIG. 3, in assembly, the latch member 50 is firstly attached to an inner side of the front panel 11. After two ends 542 of the securing pieces 54 align with inner edges of the rectangular fixing holes 13 of the front panel 11 of the chassis 10 respectively, the inner ends 543 of the slots 541 align with the screw holes 15 of the front panel 11 of the chassis 10 respectively, and the stop pieces 17 extend through the opening 53 of the latch member 50, two guiding posts 80 engage in an inner end 543 of a corresponding slot 541 of the latch member 50 and a corresponding screw hole 15 of the chassis 10 from the openings 573 of the resisting piece 57 of the latch member 50. Therefore, the latch member 50 is securely attached to the front panel 11 of the chassis 10. At that time, the stop pieces 17 of the chassis 10 extend though the opening 53 of the latch member 50 with a gap retained between the stop pieces 17 and the top and bottom edges of the opening 53 respectively.

Then the bezel 30 is attached to an outer side of the front panel 11 of the chassis 10 with its resilient fixing pieces 34 inserted into the fixing holes 13 of the front panel 11 of the chassis 10. The hooks 341 of the fixing pieces 34 of the bezel 30 are engaged with the ends 542 of the securing pieces 54 of the latch member 50 after the resilient fixing pieces 34 are elastically deformed and then rebound. The bent flanges 571 of the resisting pieces 57 of the latch member 50 resist against distal ends of the hooks 341 of the bezel 30. Thus, the hooks 341 of the fixing pieces 34 of the bezel 30 are blocked by the securing pieces 54 and the resisting pieces 57 of the latch member 50. Thus, the bezel 30 is securely attached to the front panel 11 of the chassis 10.

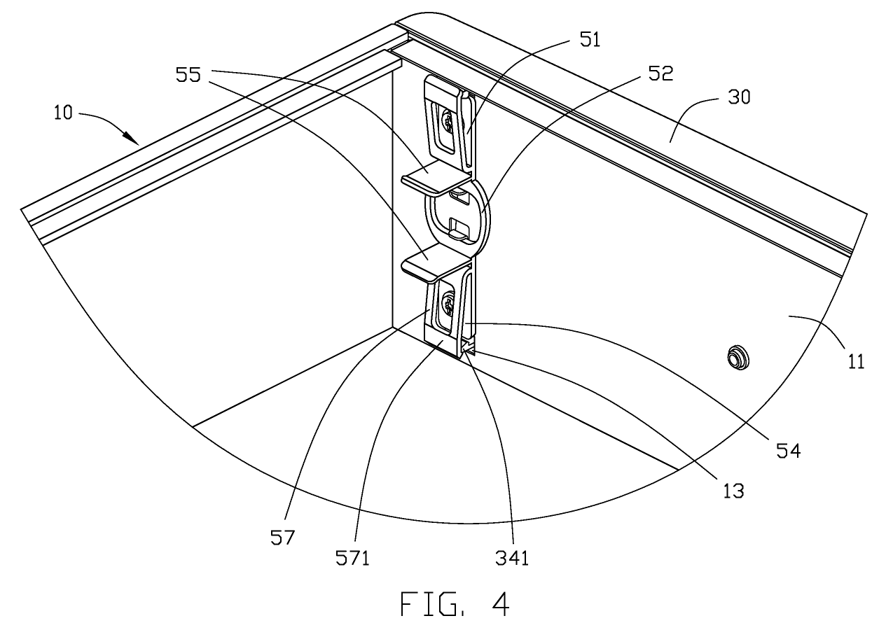

Referring also to FIG. 4, in disassembly, the handles 55 of the latch member 50 are pushed toward each other to urge the resilient arms 52 of the latch member 50 to deform outwardly, decreasing the elongated length of the body 51 of the latch member 50. After the guiding posts 80 move relative to the slots 541 of the latch member 50 until reaching the outer ends 545 of the slots 541 of the latch member 50 and the stop pieces 17 resist against the top and bottom edges of the opening 53 of the latch member 50, the hooks 341 of the resilient fixing pieces 34 of the bezel 30 disengage from the latch member 50. Then the resilient fixing pieces 34 are fully pulled out from the fixing holes 13 of the chassis 10 and the bezel 30 can then be moved from the front panel 11 of the chassis 10.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A bezel mounting assembly comprising:
a chassis comprising a front panel, and two fixing holes defined in the front panel;
a bezel attached to an outer side of the front panel, comprising two fixing pieces extending through the fixing holes of the front panel, each fixing piece having a hook formed at a distal end thereof; and
a latch member attached to an inner side of the front panel of the chassis, comprising two securing pieces removably attached on the front panel of the chassis, and a resilient segment connected between the securing pieces; wherein the resilient segment is deformable between a first natural state where the securing pieces of the latch member are lockingly engaged with the hooks of the bezel, and a second compressed state where the securing pieces are disengageable from the hooks of the bezel.

2. The bezel mounting assembly as described in claim 1, wherein the resilient segment comprises a pair of resilient arms connected between the securing pieces, and the latch member has an opening surrounded by the resilient arms and the securing pieces.

3. The bezel mounting assembly as described in claim 1, wherein distal ends of the securing pieces of the latch member align with two inner edges of the fixing holes of the front panel of the chassis respectively when the resilient segment of the latch member is at its natural state to secure the bezel, and disengage from the inner edges of the fixing holes of the front panel of the chassis and the hooks of the bezel when the resilient segment are deformed to unlock the bezel.

4. The bezel mounting assembly as described in claim 3, wherein the distance between the distal ends of the securing pieces of the latch member is approximately equal to that between the fixing holes in the front panel of the chassis.

5. The bezel mounting assembly as described in claim 1, wherein a pair of screw holes is defined in the front panel of the chassis between the fixing holes of the chassis; a pair of guiding posts for attaching the latch member to the inner side of the front panel of the chassis is engaged in the screw holes.

6. The bezel mounting assembly as described in claim 5, wherein a pair of elongated slots is defined in the securing pieces of the latch member respectively, the guiding posts are extended through the slots of the latch member and the screw holes of the chassis.

7. The bezel mounting assembly as described in claim 6, wherein the guiding posts are received in inner ends of the slots of the latch member when the resilient segment of the latch member is at its natural state to secure the bezel, and received in outer ends of the slots of the latch member when the resilient segment is deformed to pull the securing pieces of the latch member closer to each other to unlock the bezel.

8. The bezel mounting assembly as described in claim 1, wherein the latch member further comprises a pair of handles extending perpendicularly from junction ends between the securing pieces and the resilient segment.

9. A bezel mounting assembly comprising:
a chassis comprising a front panel, and two fixing holes defined in the front panel;
a bezel attached to an outer side of the front panel, comprising two fixing pieces inserted though the fixing holes of the chassis, each fixing piece having a hook formed at a distal end thereof in the chassis; and
a latch member attached to an inner side of the front panel of the chassis, comprising a resilient body retractable between an original position where two distal ends of the resilient body are engaged with the hooks of the bezel to secure the bezel, and a retracted position where the resilient body is compressed and elastically deformed to disengage the distal ends of the resilient body from the hooks of the bezel to unlock the bezel.

10. The bezel mounting assembly as described in claim 9, wherein the body of the latch member respectively comprises two securing pieces at two ends thereof, and two resilient arms connected between the securing pieces; an opening defined in the body is surrounded by the securing pieces and the resilient arms.

11. The bezel mounting assembly as described in claim 10, wherein the resilient arms are arc-shaped and protrude out a short distance beyond two side edges of the body of the latch member.

12. The bezel mounting assembly as described in claim 10, wherein two screw holes are defined in the front panel of the chassis between the fixing holes of the chassis; two elongated slots are defined in the two securing pieces of the latch member respectively; a pair of guiding posts extend through the slot of the latch member and the screw holes of the chassis for attaching the latch member to the chassis.

13. The bezel mounting assembly as described in claim 12, wherein when the body of the latch member is at the original position to secure the bezel, the guiding posts are engaged in inner ends of the slots of the latch member respectively; when the body of the latch member is at the retracted position to unlock the bezel, the guiding posts are engaged in outer ends of the slots of the latch member respectively.

14. The bezel mounting assembly as described in claim 10, wherein the latch member further comprises two handles extending perpendicularly from junction ends between the securing pieces and the resilient arms respectively for facilitating compressing the resilient arms.

15. The bezel mounting assembly as described in claim 14, wherein the latch member further comprises two resisting pieces extending obliquely from the junctions ends, the hooks of the bezel are blocked firmly by the resisting pieces and the securing piece of the latch member to secure the bezel.

16. A computer enclosure comprising:
a chassis comprising a front panel and two fixing holes defined in the front panel;
a bezel attached to an outer side of the front panel, the bezel comprising two resilient hooks extending through the fixing holes of the front panel; and
a resilient elongated latch member attached to an inner side of the front panel of the chassis, the latch member comprising two securing portion attached on the front panel of the chassis, and an intermediate linking portion interconnected between the securing portion; the securing portions being slidably movable toward each other on the front panel and being configured for lockingly engaged with the hooks of the bezel, the intermediate linking portion being lengthwise deformable between a first natural state where the securing portions of the latch member are lockingly engaged with the hooks of the bezel, and a second compressed state where the securing portion are disengaged from the hooks of the bezel.

17. The computer enclosure as described in claim 16, wherein the front panel includes two guiding posts and the securing portions each includes a slot defined therein with the guiding posts extending therethrough, the slot extending in the lengthwise direction of the latch member.

18. The computer enclosure as described in claim 16, wherein latch member includes two resisting pieces configured for pressing the hooks toward each other.
